(19) United States
(12) Patent Application Publication
(10) Pub. No.: US 2025/0203763 A1
(43) Pub. Date: Jun. 19, 2025

(54) FLEXIBLE CIRCUIT BOARD AND METHOD FOR MANUFACTURING SAME

(71) Applicant: Heraeus Medevio GmbH & Co. KG, Hanau (DE)

(72) Inventor: Ilias NIKOLAIDIS, Hanau (DE)

(21) Appl. No.: 18/973,897

(22) Filed: Dec. 9, 2024

(30) Foreign Application Priority Data
Dec. 14, 2023 (DE) 102023135112.5

(51) Int. Cl. H05K 1/02; H05K 3/46

(52) U.S. Cl. CPC H05K 1/0277; H05K 3/4644

(57) ABSTRACT

A flexible circuit board for electrically connecting electrical components of a medical device, comprising a plurality of conductor layers, wherein an electrically insulating layer is formed between adjacent conductor layers and on a top face, wherein the circuit board contains at least one contact opening that extends from the top face to the conductor layers to be contacted in order to enable electrical components to be electrically connected to the individual conductor layers to be contacted.

### CROSS-REFERENCE TO RELATED APPLICATIONS

This application claims priority pursuant to 35 U.S.C. 119(a) to German Application No. 102023135112.5, filed Dec. 14, 2023, which application is incorporated herein by reference in its entirety.

### FIELD OF THE INVENTION

The invention relates to a flexible circuit board for electrically connecting electrical components of a medical device, comprising a plurality of conductor layers, wherein an electrically insulating layer is formed between adjacent conductor layers and on a top face, wherein the circuit board contains at least one contact opening that extends from the top face to the conductor layers to be contacted in order to enable electrical components to be electrically connected to the individual conductor layers to be contacted.

### BACKGROUND OF THE INVENTION

Flexible circuit boards (FCBs) are used in many areas of technology, in particular also for medical devices, as electrical connecting elements and circuit carriers. Commercially available circuit boards comprise a plurality of conductor tracks that are electrically insulated from one another and arranged between two electrically insulating layers.

By selectively opening one or both insulating layers, a corresponding conductor track from the plurality of conductor tracks can be specifically electrically contacted and thus electrical components, in particular electrodes, for example ring electrodes, or electrical components for measuring electrical signals or for stimulation applications, can be connected to one another.

To manufacture such circuit boards, a conductor layer, such as a copper foil, is usually applied to an insulating layer and then subjected to a structuring process. The desired conductor track design is obtained by removing material from the conductor layer, for example by etching or laser ablation.

The final electrical circuit of the circuit board is therefore already determined during manufacture by structuring the conductor layer, which limits the use of the circuit board to a specific application. Such manufacture is also complex and therefore costly.

Considerable efforts are therefore being made to simplify the construction of flexible conductor tracks and to make them flexibly usable for the widest possible range of applications. There is also a desire for a manufacturing method that is as cost-effective as possible.

### SUMMARY OF THE INVENTION

A contribution to the at least partial fulfillment of at least one of the aforementioned objects is made by the features of the independent claims. The dependent claims provide preferred embodiments that contribute to the at least partial fulfillment of at least one of the objects.

A first embodiment of the invention is a flexible circuit board for electrically connecting electrical components of a medical device, comprising a plurality of conductor layers, wherein an electrically insulating layer is formed between adjacent conductor layers and on a top face, wherein the circuit board contains at least one contact opening that extends from the top face to the conductor layers to be contacted in order to enable electrical components to be electrically connected to the individual conductor layers to be contacted, characterized in that the contact opening for electrical connection to an n-th conductor layer as seen from the top face contains n electrically insulating step-like shoulders, formed from the insulating layer forming the top face and the n-1 insulating layers lying between the top face and the n-th conductor layer.

In a preferred embodiment of the flexible circuit board, the electrically insulating step-like shoulders on an insulating layer side facing the top face are free of electrically conductive material. This embodiment is a second embodiment of the invention, which is preferably dependent on the first embodiment of the invention.

In a preferred embodiment of the flexible circuit board, the conductor layers have a conductor layer thickness in a range from 0.1 μm to 5 μm. This embodiment is a third embodiment of the invention, which is preferably dependent on the first or second embodiment of the invention.

In a preferred embodiment of the flexible circuit board, the conductor layer accessible via the contact opening, preferably all conductor layers accessible via the contact openings, contains a contact point with a contact point thickness that is greater than the conductor layer thickness. This embodiment is a fourth embodiment of the invention, which is preferably dependent on the third embodiment of the invention.

In a preferred embodiment of the flexible circuit board, the contact point comprises a metal strip, a sintered metal paste, a dried conductive paste or a combination of the aforementioned alternatives. This embodiment is a fifth embodiment of the invention, which is preferably dependent on the fourth embodiment of the invention.

In a preferred embodiment of the flexible circuit board, the contact point thickness is in a range from 3 μm to 100 μm, preferably in a range from 10 μm to 50 μm. This embodiment is a sixth embodiment of the invention, which is preferably dependent on the fourth or fifth embodiment of the invention.

In a preferred embodiment of the flexible circuit board, the insulating layers have an insulating layer thickness in a range of 5 μm to 20 μm. This embodiment is a seventh embodiment of the invention, which is preferably dependent on one of the preceding embodiments of the invention.

In a preferred embodiment of the flexible circuit board, the circuit board contains at least 5, preferably at least 10, more preferably at least 12 conductor layers. Preferably, the number of circuit boards is in a range of 5 to 25, preferably in a range of 5 to 20, more preferably in a range of 5 to 15. This embodiment is an eighth embodiment of the invention, which is preferably dependent on one of the preceding embodiments of the invention.

In a preferred embodiment of the flexible circuit board, the conductor layers comprise platinum, iridium or platinum and iridium. Preferably, the circuit boards consist of at least 80 percent by weight of platinum, iridium or platinum and iridium based on the total weight of the conductor layers. This embodiment is a ninth embodiment of the invention, which is preferably dependent on one of the preceding embodiments of the invention.

In a preferred embodiment of the flexible circuit board, the insulating layers comprise a polyimide, a polyetheretherketone (PEEK) or a polyimide and a polyetheretherketone. Preferably, the insulating layers consist of a polyimide, a polyetheretherketone or of a polyimide and a polyetheretherketone. This embodiment is a tenth embodiment of the invention, which is preferably dependent on one of the preceding embodiments of the invention.

An eleventh embodiment of the invention is a method for manufacturing a flexible circuit board according to one of the preceding embodiments of the invention, comprising the following method steps:
a) providing an insulating layer;
b) coating the insulating layer with a conductor layer;
c) coating the conductor layer with a further insulating layer;
d) repeating method steps b) and c) at least once until a desired number of conductor layers have been built up, wherein each additional conductor layer in method step b) is applied to an insulating layer previously created in method step c);
e) making the at least one contact opening.

In a preferred embodiment of the method, the coating in method step b) is carried out using a conductive ink. This embodiment is a twelfth embodiment of the invention, which is preferably dependent on the eleventh embodiment of the invention.

In a preferred embodiment of the method, the coating in method step c) is carried out by means of a lamination step. This embodiment is a thirteenth embodiment of the invention, which is preferably dependent on the eleventh or twelfth embodiment of the invention.

In a preferred embodiment of the method, after method step b), in a method step b1), a contact point according to one of the fourth to sixth embodiments of the invention is arranged on the conductor layer. This embodiment is a fourteenth embodiment of the invention, which is preferably dependent on one of the eleventh to thirteenth embodiments of the invention.

In a preferred embodiment of the method, method step e) is carried out by means of laser ablation. This embodiment is a fifteenth embodiment of the invention, which is preferably dependent on the eleventh to fifteenth embodiments of the invention.

One object of the present invention is to overcome, at least in part, one or more of the disadvantages resulting from the prior art.

It is a further object of the invention to provide a flexible circuit board that can be used or modified for as many different applications as possible.

It is a further object of the invention to provide a method for manufacturing a flexible circuit board by means of which at least some of the objects already described are at least partially achieved.

It is a further object of the invention to provide a method with as few and simple method steps as possible for manufacturing a flexible circuit board. In particular, the method should be as simple and quick to carry out as possible and thus cost-effective.

### DETAILED DESCRIPTION OF THE INVENTION

In addition to the embodiments described herein, the elements of which “contain” or “comprise” a particular feature (e.g. a material), a further embodiment is always contemplated in which the element in question consists solely of the feature, i.e., does not comprise any other components. The word “comprise” or “comprising” is herein used synonymously with the word “contain” or “containing.”

When in an embodiment an element is referred to in the singular, an embodiment is also contemplated in which several of these elements are present. The use of a term for an element in the plural generally also includes an embodiment in which only a single corresponding element is included.

Unless otherwise stated or clearly excluded from the context, it is fundamentally possible and is hereby clearly considered that features of different embodiments can also be provided in the other embodiments described herein. It is also generally contemplated that all features described herein in connection with a method are also applicable to the products and devices described herein, and vice versa.

Merely for the sake of conciseness, these considered combinations are not all explicitly listed in all cases. Technical solutions that are known to be equivalent to the features described herein should also be included in principle in the scope of the invention.

In the present description, specifications of ranges also contain the values specified as limits. A specification of the type “in the range from X to Y” with respect to a quantity A consequently means that A can take the values X, Y and values between X and Y. Ranges which are limited on one side, of the type “up to Y” for a size A, accordingly mean a value Y and less than Y.

Some of the features described are associated with the term “substantially.” The term “substantially” is to be understood in such a way that, under real conditions and manufacturing techniques, a mathematically exact interpretation of terms such as “superimposition,” “perpendicular,” “diameter” or “parallelism” can never be given exactly, but only within certain manufacturing error tolerances. For example, “substantially perpendicular axes” enclose an angle of 85 degrees to 95 degrees relative to one another, and “substantially equal volumes” comprise a variation of up to 5% by volume. For example, a “device consisting substantially of plastics” comprises a plastics content of ≥95 to ≤100% by weight. For example, a “substantially complete filling of a volume B” comprises a filling of ≥95 to ≤100% by volume of the total volume of B.

A first subject of the invention relates to a flexible circuit board for electrically connecting electrical components of a medical device, comprising a plurality of conductor layers, wherein an electrically insulating layer is arranged and/or formed between adjacent conductor layers and on a top face, wherein the circuit board contains at least one contact opening that extends from the top face to the conductor layers to be contacted in order to enable electrical components to be electrically connected to the individual conductor layers to be contacted, wherein the contact opening for electrical connection to an n-th conductor layer as seen from the top face contains n electrically insulating step-like shoulders, formed from the insulating layer forming the top face and the n-1 insulating layers lying between the top face and the n-th conductor layer.

The flexible circuit board is used to electrically connect electrical components of a medical device. For this purpose, the circuit board contains a plurality, i.e., two or more, conductor layers, in particular electrically conductive conductor layers. Preferably, each of the conductor layers serves to electrically connect exactly two electrical components to each other via the circuit board.

Preferably, the conductor layers comprise or consist of an electrically conductive metal.

The individual conductor layers are electrically insulated from one another by insulating layers arranged between the conductor layers. The insulating layers are substantially not electrically conductive. For example, the insulating layers are made of an electrically non-conductive polymer. At least a top face, preferably both the top face and an underside of the circuit board opposite the top face, is or are provided with an insulating layer so that the circuit board is electrically insulated in this direction. Preferably, the circuit board is also electrically insulated on the side faces.

The dimensions of the circuit board are therefore preferably determined by the dimensions of the insulating layers. Preferably, all insulating layers have substantially the same dimensions. The exact dimensions depend on the intended application of the circuit boards. For example, the circuit board can have a length in a range of 10 cm to 200 cm and/or a width in a range of 0.5 mm to 2 mm.

Preferably, the conductor layers have substantially the same dimensions as the insulating layers. The insulating layers are thus preferably substantially completely covered with the conductor layers, at least on one of their sides. In one embodiment, the insulating layers are substantially free of conductive material at least at their edges, in particular their side edges, so that the circuit board is electrically insulated on the outside, in particular on its side faces.

Preferably, there is in each case only a single conductor layer between two adjacent insulating layers. Each conductor layer therefore preferably represents a single conductor track that connects or can connect two electrical components to each other.

In order to electrically contact the individual conductor layers to electrical components, the circuit board contains at least one contact opening. For example, the circuit board contains two or three contact openings. The circuit board can also contain as many contact openings as conductor layers. The contact opening extends from the top face of the circuit board, in particular from the insulating layer of the circuit board forming the top face, down to the desired n-th conductor layer to be electrically contacted. For example, the contact opening represents an opening that extends from the top face through two conductor layers and the corresponding insulating layers therebetween to a third conductor layer as seen from the top face. This type of contact opening thus allows electrical contacting of up to three conductor layers.

A contact opening preferably represents an at least partial removal of material from the individual insulating and conductor layers, starting with the insulating layer on the top face of the circuit board down to the n-th conductor layer as seen from the top face, wherein this n-th conductor layer is substantially completely preserved.

In order to selectively electrically contact an individual conductor layer accessible via the contact opening and thus to specifically not electrically contact other conductor layers that are also accessible via the same contact opening, electrically insulating step-like shoulders are formed in the contact opening, which electrically insulate the individual conductor layers within the contact opening from one another. These shoulders are designed in steps, so that a contacting element, for example a wire, or directly an electrical component, which is introduced into the contacting opening substantially vertically from the direction of the top face, only comes into contact with the desired conductor layer and not with the other accessible conductor layers. The step-like design thus spatially separates the contact points of the individual conductor layers accessible via the contact opening from one another.

The number of step-like shoulders depends on the number of conductor layers that are accessible via a single contact opening. The more conductor layers are accessible, the more shoulders are needed to reliably ensure a selective electrical connection of the individual conductor layers to electrical components.

A contact opening that extends to an n-th conductor layer as seen from the top face therefore contains n shoulders. The shoulders are formed from the insulating layers, wherein the insulating layer forming the top face of the circuit board forms a first shoulder, and the n-1 insulating layers lying between the top face and the n-th conductor layer form the further shoulders. For example, a contact opening extends to the third conductor layer as seen from the top face. This contact opening thus contains three shoulders, the first shoulder being formed from the insulating layer forming the top face, and the two further shoulders being formed from the insulating layers between the first and second conductor layers as seen from the top face and between the second and third conductor layers as seen from the top face.

Preferably, the step-like shoulders are formed from a flank, or at least a part of a flank, of the insulating layers and a portion of an insulating layer side of the insulating layers that faces the top face of the circuit board or, in the case of the insulating layer forming the top face, the top face of this insulating layer. A flank corresponds to the portion of the shoulder that extends along a thickness of the insulating layer.

An electrically insulating edge is thus preferably formed between the flank and the top face of the insulating layer.

Preferably, the flank extends substantially perpendicularly to the top face of the circuit board, so that the flank substantially corresponds to the thickness of an insulating layer. In this embodiment, the shoulder contains an edge with an interior angle between the flank and the insulating layer side facing the top face of substantially 90°.

An embodiment of the circuit board is characterized in that the electrically insulating step-like shoulders on the insulating layer side facing the top face are free of electrically conductive material, in particular free of the material of the conductor layer. In this embodiment, the flank and the portion of the insulating layer free of electrical material form the step-like shoulder.

Depending on the application of the circuit board, the portion of the insulating layer side facing the top face that is free of electrically conductive material can have different spatial dimensions. For example, the extension of the free portion can be in the range of the extension of the flank, in particular in the range of the thickness of the insulating layers. For example, the portion can extend from the edge in a range of 20 μm to 200 μm. This range ensures that the individual conductor layers can be selectively contacted and that accidental short circuits do not occur between the individual conductor layers.

The conductor layers can have different thicknesses depending on the application of the circuit board.

An embodiment of the circuit board is characterized in that the conductor layers have a conductor layer thickness in a range of 0.1 μm to 5 μm.

This range ensures sufficient conductivity of the conductor layer while maintaining maximum flexibility. Furthermore, this range allows the conductor layers and thus the circuit board to be manufactured as cost-effectively as possible.

The conductor layers accessible via the contact opening can be contacted directly electrically, for example via a wire.

An embodiment of the circuit board is characterized in that the conductor layer accessible via the contact opening, in particular all conductor layers accessible via the contact opening, contains a contact point, in particular an electrically conductive contact point, with a contact point thickness that is greater than the conductor layer thickness, in particular the conductor layer thickness adjacent to the contact point. The contact point thus represents an electrically conductive material reinforcement of some portions of the conductor layer, which facilitates electrical contacting of the conductor layer.

Preferably, the contact opening is created by removing material from the corresponding layers so that the contact point can compensate for any resulting process fluctuations. For example, the contact opening is created by means of laser ablation, and the contact point ensures that a slightly increased material removal still leaves enough electrically conductive material on the conductor layer(s) to make safe and reliable electrical contact with them.

A single conductor layer can contain one or more contact points. Preferably, each conductor layer that is accessible via a common contact opening contains at least one, preferably exactly one contact point, in the region of the contact opening.

The contact point can be realized in different ways to facilitate electrical contacting of the conductor layer accessible via the contact opening. For example, the conductor layer can be made thicker at the corresponding location in order to form the contact point.

An embodiment of the circuit board is characterized in that the contact point comprises a metal strip, a sintered metal paste, a dried conductive paste or a combination of the aforementioned materials. Preferably, the contact point consists of a metal strip of a sintered metal paste, a dried metal paste or a combination of the aforementioned materials.

In order to produce the contact point from a sintered metal paste, a metal paste, i.e., a metal powder in a carrier material, such as an organic solvent, preferably comprising a thickener, such as a cellulose, can be applied, for example printed on, to the corresponding location. After application, the metal paste can be heated so that the solvent evaporates and the metal powder at least partially sinters together, thus forming the contact point.

In order to produce the contact point from a dried conductive paste, a conductive paste, i.e., a carrier material filled with a metal powder, such as a polymer or a polymer dissolved in a solvent, can be applied, for example printed on, to the corresponding location. After application, the conductive paste can be heated so that it hardens and forms the contact point.

Preferably, the contact point is formed from a metal strip that is arranged on the conductor layer. For example, the metal strip is attached to the conductor layer with a conductive adhesive or a conductive paste. Any type of attachment of the metal strip to the conductor layer is conceivable, as long as there is an electrically conductive connection between the conductor layer and the metal strip.

A metal strip is preferred because such a contact point is particularly easy to produce and allows a particularly simple to implement and stable electrical connection to an electrical component. In addition, material removal, preferably by means of laser ablation, down to a metal strip to form the contact opening is particularly easy to implement.

An embodiment of the circuit board is characterized in that the contact point thickness is in a range from 3 μm to 100 μm, preferably in a range from 10 μm to 50 μm.

An embodiment of the circuit board is characterized in that the insulating layers have an insulating layer thickness in a range of 5 μm to 20 μm. This range ensures sufficient insulating capacity of the insulating layers while maintaining the greatest possible flexibility.

The circuit board can contain a different number of conductor layers, and thus also insulating layers. The number of conductor layers depends on the intended application of the circuit board. Each conductor layer can be used for at least one, preferably exactly one, electrical connection between two electrical components.

An embodiment of the circuit board is characterized in that the circuit board contains at least 5, preferably at least 10, more preferably at least 12 conductor layers. Preferably, the circuit board contains a number of conductor layers that is in a range of 5 to 25, preferably in a range of 5 to 20, more preferably in a range of 5 to 15. The upper limit of the specified range also represents an upper limit for n. An increase in the number of conductor layers is accompanied by an increase in the possible electrical connections that can be realized via the circuit board, especially with exactly one electrical connection per conductor layer. At the same time, increasing the number of conductor layers reduces the flexibility of the circuit board.

The conductor layers may comprise different electrically conductive materials or consist of different electrically conductive materials. For example, the conductor layers can be made of an electrically conductive polymer, such as poly-3,4-ethylenedioxythiophene (PEDOT). Due to the better conductivity, it is preferred that the conductor layers comprise an electrically conductive metal or consist of such a metal. For example, the conductor layers are made of silver, gold or alloys containing silver and/or gold.

An embodiment of the circuit board is characterized in that the conductor layers comprise platinum, iridium or platinum and iridium or consist of platinum, iridium or platinum and iridium. Such conductor layers have good biocompatibility.

The insulating layers may comprise different electrically insulating materials or consist of different electrically insulating materials.

An embodiment of the circuit board is characterized in that the insulating layers comprise a polyimide, a polyetheretherketone (PEEK) or a polyimide and a polyetheretherketone or consist of a polyimide, a polyetheretherketone or of a polyimide and a polyetheretherketone. Other preferred insulating layers comprise a polyurethane, a polyether block amide block copolymer (PEBAX) or a polyurethane and a polyether block amide block copolymer or consist of these materials. Further preferred insulating layers comprise a mixture of all of the aforementioned materials or consist of a mixture of all of the aforementioned materials. Such insulating layers are easy to produce and have good flexibility.

A further subject of the invention relates to a method for manufacturing a flexible circuit board according to one of the preceding embodiments of the invention, comprising the following method steps:
a) providing an insulating layer;
b) coating the insulating layer with a conductor layer;
c) coating the conductor layer with a further insulating layer;
d) repeating method steps b) and c) at least once until a desired number of conductor layers have been built up, wherein each additional conductor layer in method step b) is applied to an insulating layer previously created in method step c);
e) making the at least one contact opening.

In a method step a), an insulating layer is provided. The insulating layer can have the dimensions of the circuit board to be manufactured, in particular its length and width. In a preferred embodiment, the insulating layer provided substantially represents the final width of the circuit board to be manufactured, but is provided with a multiple of its final length. Preferably, the insulating layer is provided as a roll with the multiple of the final length of the circuit board to be manufactured, so that it can be shortened to the desired length in a later method step.

In a method step b), the insulating layer provided in method step a) is coated with a conductor layer. Coating can be carried out in different ways. For example, the coating can be carried out by gluing or laminating a provided conductor layer, for example in the form of a metal foil, onto the insulating layer. In a preferred embodiment of method step b), the coating is carried out by means of a dip coating process, wherein the insulating layer is passed through a reservoir containing a liquid that is converted into the conductor layer by heat treatment or an irradiation process. Preferably, this liquid is a conductive ink that can be converted into the conductor layer by heat treatment.

Preferably, the conductive ink is an ink that produces a conductor layer comprising platinum, iridium or platinum and iridium by heat treatment.

Preferably, the conductive ink for applying a conductor layer comprising platinum consists of:
(A) 30 to 90% by weight of at least one organic solvent,
(B) 10 to 70% by weight of at least one platinum complex of the type [L1L2Pt[O(CO)R1]X]ₘ, where L1 and L2 are identical or different monoolefin ligands or together represent a compound L1L2 acting as a diolefin ligand, where X is selected from bromide, chloride, iodide, and —O(CO)R2, where —O(CO)R1 and —O(CO)R2 represent the same or different non-aromatic C6-C18 or preferably C8-C18 monocarboxylic acid groups or together represent a C8-C18 non-aromatic dicarboxylic acid group —O(CO)R1R2(CO)O—, wherein the platinum complexes are mononuclear platinum complexes with m=1, or wherein, if L1L2 and/or —O(CO)R1R2(CO)O— are present, the platinum complexes may be polynuclear platinum complexes with an integer m>1, and
(C) 0 to 10% by weight of at least one additive.

For more specific embodiments of the platinum-containing conductive ink and the application thereof, reference is made to patent application WO 2021/089203 A1, which is hereby incorporated by reference.

Preferably, the conductive ink for applying a conductor layer comprising iridium consists of:
(A) 30 to 90% by weight of at least one organic solvent,
(B) 10 to 70% by weight of at least one iridium complex with diolefin and C6-C18 monocarboxylate ligands selected from the group consisting of noble metal complexes of the type [LIr[O(CO)R1]]ₘ, where L is a compound acting as a diolefin ligand, where X is selected from bromide, chloride, iodide and —O(CO)R2, where —O(CO)R1 and —O(CO)R2 are identical or different non-aromatic C6-C18 monocarboxylic acid groups, each preferably with the exception of a phenylacetic acid group, and where m is an integer ≥2, and
(C) 0 to 10% by weight of at least one additive.

For more specific embodiments of the iridium-containing conductive ink and the application thereof, reference is made to patent application EP 3 940 110 A1, which is hereby incorporated by reference.

Preferably, the coating with the conductive ink is carried out in a roll-to-roll process, as this is easy to carry out and allows a cost-effective coating of the insulating layer with the conductor layer. Depending on the desired thickness of the conductor layer, the coating process can also be carried out several times, for example two or three times, in succession.

If desired, coating with the liquid, preferably the conductive ink, may result in a conductor layer on both sides of the insulating layer provided in method step a). If a conductor layer is only desired on one side of the insulating layer, the liquid can be removed again from one side of the conductor layer before the conductor layer is formed, i.e., preferably before the liquid is heat treated or irradiated. For example, the liquid can be stripped off one side of the insulating layer so that no coating with a conductor layer takes place on that side.

Preferably, the liquid is removed at least from the two side faces that correspond to the thickness of the insulating layer before conversion into the conductor layer, or this region is removed in a later method step, for example by cutting off.

In a method step c), the conductor layer, in particular the conductor layer applied in method step b), is coated with a further insulating layer. Thus, at least one conductor layer is provided, which is surrounded on both sides by an insulating layer. If in method step b) the insulating layer provided in method step a) is coated on both sides, it is preferred that the two conductor layers are coated with a further insulating layer.

Coating the conductor layer with a further insulating layer can be achieved in different ways. For example, coating can be done by a lamination process with a prefabricated further insulating layer. A further possibility is a dip coating process analogous to the previously described process in method step b), wherein the liquid this time is preferably a dielectric ink, which is preferably converted into the further insulating layer by heat treatment or irradiation.

Preferably, the further insulating layer consists of the same material as the insulating layer provided in method step a).

In order to construct a circuit board with a plurality of conductor layers, method steps b) and c) are repeated at least once in a method step d). Each repetition of these method steps produces at least one further conductor layer in addition to the conductor layer(s) already present.

After obtaining the desired number of layers of the circuit board, in particular all desired conductor layers and all desired insulating layers, the at least one contact opening is made in a method step e). Preferably, the at least one contact opening is made by removing material from the layers to form the electrically insulating step-like shoulders.

Material removal can be achieved in different ways. In one embodiment, a separating layer is introduced between the individual layers, in particular between adjacent conductor and insulating layers. Once all layers of the circuit board have been completed, the separating layers are used to separate all layers above or below the separating layer from the rest of the circuit board by peeling them off, at least in the dimensions of the separating layer, and thus to form the contact opening. The individual separating layers are arranged in relation to one another in such a way that the desired design of the contact opening is obtained by peeling off the separating layers.

For example, the separating layer is a layer of paper that is applied to a conductor layer before a lamination step of an insulating layer. In a further embodiment, the separating layer is a layer, preferably a polymer layer, for example made of a polyimide, on the contact points, for example on one or all of the metal strips. This separating layer can be peeled off from the contact point in such a way that all layers above it are separated and the contact point previously coated with the separating layer is accessible via the newly created contact opening.

Preferably, the separating layers protrude from the sides of the circuit board so that they are easily accessible and can be easily peeled off in order to form the contact opening.

In another embodiment, the material is removed by laser ablation.

If necessary, the circuit board can be cut to a desired length and/or width in a further method step. Preferably, cutting to size takes place after method step e).

Optionally, in a method step b1) after method step b), a contact point can be arranged on the conductor layer. Preferably, this step is carried out by applying a metal strip to the conductor layer created in method step b). The contact point can be applied simultaneously with the coating of the conductor layer with the further insulating layer in method step c). For example, metal strips can be provided attached to a prefabricated further insulating layer, and this insulating layer can be laminated to the conductor layer so that the metal strips are arranged on the conductor layer. Method step b1) can optionally be carried out in at least one, preferably all, repetitions of method steps b) and c) in method step d).

The features disclosed for the circuit board are also disclosed for the method for manufacturing the circuit board, and vice versa.

### BRIEF DESCRIPTION OF THE DRAWINGS

The invention is further illustrated by way of example below by means of figures. The invention is not limited to the figures.

In the figures:

FIG. 1 shows a schematic longitudinal section of an exemplary flexible circuit board;

FIG. 2 shows a schematic exemplary method step for manufacturing the circuit board from FIG. 1; and,

FIG. 3 shows a schematic further exemplary method step for manufacturing the circuit board from FIG. 1.

### DESCRIPTION OF THE FIGURES

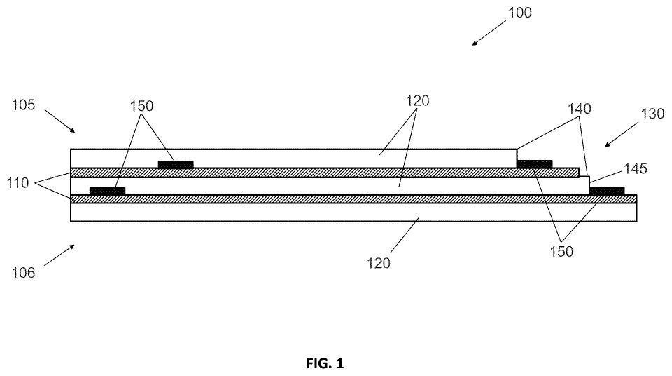

FIG. 1 shows a schematic longitudinal section of an exemplary flexible circuit board 100. The circuit board 100 contains two conductor layers 110. An insulating layer 120 is arranged in each case between the conductor layers 110 and on a top face 105 and on an underside 106 of the circuit board 100 opposite the top face 105. The conductor layers 110 are electrically insulated from each other by the insulating layer 120 located between them. In order to electrically contact the two conductor layers 110 from the top face 105, for example with an electrical component (not shown), the circuit board 100 contains a contact opening 130. In the region of the contact opening 130, the conductor layers 110 are at least partially not covered by the respective insulating layers 120, as seen from the top face 105. In order to avoid short circuits and at the same time to allow a selective electrical connection of the conductor layers 110, the circuit board 100 contains two electrically insulating step-like shoulders 140 in the region of the contact opening 130. The step-like shoulders 140 are formed from the insulating layer 120 forming the top face 105 and lying between the two conductor layers 110. In particular, the shoulders 140 consist of the flanks 145 (provided with reference signs only as an example) of the corresponding insulating layers 120 and a portion on an insulating layer side facing the top face 105, which is free of electrically conductive material, in particular free of the material of the conductor layers 110.

In order to improve the electrical connection of the individual conductor layers 110 of the circuit board 100 to electrical components (not shown), the two conductor layers 110 each contain axially spaced contact points 150 in the form of metal strips, wherein in each case one of the contact points 150 of the two conductor layers 110 is exposed in the region of the contact opening 130. The metal strips extend substantially across the width of the circuit board 100. In the region of the non-exposed contact points 150, i.e., the metal strips lying between a conductor layer 110 and an insulating layer 120, a further contact opening could be formed. The metal strips simplify the production of this further contact opening by means of laser ablation, since the metal strip can compensate for possible manufacturing variations due to its greater thickness compared to the conductor layer 110. In addition, the contact points allow simplified electrical contacting of the circuit board 100 with electrical components.

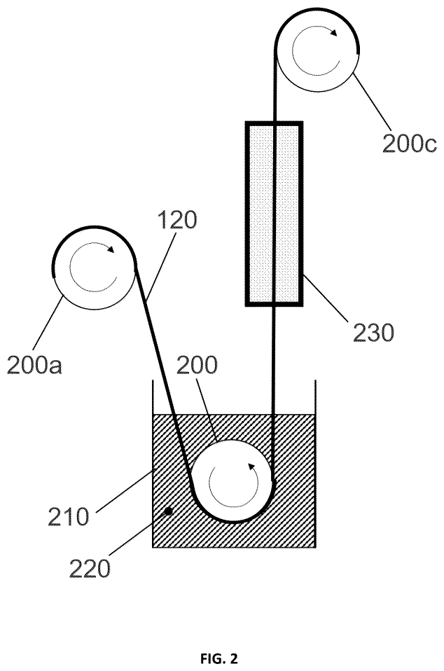

FIG. 2 shows a schematic exemplary method step for manufacturing the circuit board 100 from FIG. 1. An insulating layer 120 is provided on a roller 200a and passed over another roller 200b within a reservoir 210 filled with a conductive ink 220. The insulating layer 120 coated with the conductive ink 220 by means of this dip coating process is subjected to a heat treatment step in an oven 230, which converts the conductive ink 220 into a conductor layer 110 (cf. FIG. 1). The insulating layer 120 thus coated is diverted via another roller 200c for further processing. For example, the further processing may consist of repeating the method step described in FIG. 2 in order to increase an insulating layer thickness of the insulating layer 110. Alternatively, the further processing may consist of a coating with a dielectric ink, this being possible analogously to the method step described in FIG. 2, wherein the conductive ink 220 is replaced by a dielectric ink.

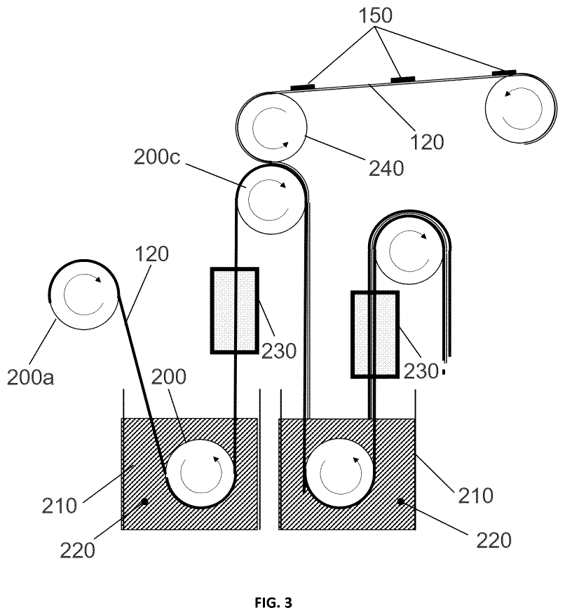

FIG. 3 shows a schematic exemplary method step for manufacturing the circuit board 100 from FIG. 1. The manufacturing starts analogously to FIG. 2 with the coating of the insulating layer 120 with a conductor layer (not shown) by means of a dip coating process. To avoid repetition, reference is made to the statements made in relation to FIG. 2.

After coating with the conductor layer (not shown), a further insulating layer 120 provided with metal strips is applied to the conductor layer via a laminating roller 240. This is followed by a repetition of a dip coating process, optionally with further lamination steps, until a desired number of conductor layers is built up.

Optionally, the metal strips 150 can be omitted in the lamination step to manufacture a circuit board without contact points.

### REFERENCE SIGNS

100 flexible circuit board
105 top face
106 underside
110 conductor layer
120 insulating layer
130 contact opening
140 step-like shoulder
150 contact point
200a, 200b, 200c roller
210 reservoir
220 conductive ink
230 oven
240 laminating roller

1. A flexible circuit board for electrically connecting electrical components of a medical device, comprising a plurality of conductor layers, wherein an electrically insulating layer is formed between adjacent conductor layers and on a top face, wherein the circuit board contains at least one contact opening that extends from the top face to the conductor layers to be contacted in order to enable electrical components to be electrically connected to the individual conductor layers to be contacted, wherein the contact opening for electrical connection to an n-th conductor layer as seen from the top face contains n electrically insulating step-like shoulders, formed from the insulating layer forming the top face and the n-1 insulating layers lying between the top face and the n-th conductor layer.

2. The flexible circuit board according to claim 1, wherein the electrically insulating step-like shoulders are free of electrically conductive material on an insulating layer side facing the top face.

3. The flexible circuit board according to claim 1, wherein the conductor layers have a conductor layer thickness in a range of 0.1 μm to 5 μm.

4. The flexible circuit board according to claim 3, wherein the conductor layer accessible via the contact opening contains a contact point with a contact point thickness that is greater than the conductor layer thickness.

5. The flexible circuit board according to claim 4, wherein the contact point comprises a metal strip, a sintered metal paste and/or a dried conductive paste.

6. The flexible circuit board according to claim 4, wherein the contact point thickness is in a range of 3 μm to 100 μm.

7. The flexible circuit board according to claim 1, wherein the insulating layers have an insulating layer thickness in a range of 5 μm to 20 μm.

8. The flexible circuit board according to claim 1, wherein the circuit board contains at least 5 conductor layers.

9. The flexible circuit board according to claim 1, wherein the conductor layers comprise platinum and/or iridium.

10. The flexible circuit board according to claim 1, wherein the insulating layers comprise a polyimide and/or a polyetheretherketone.

11. A method for manufacturing a flexible circuit board according to claim 1, comprising the following method steps:
a) providing an insulating layer;
b) coating the insulating layer with a conductor layer;
c) coating the conductor layer with a further insulating layer;
d) repeating method steps b) and c) at least once until a desired number of conductor layers have been built up, wherein each further conductor layer in method step b) is applied to an insulating layer previously created in method step c);
e) making the at least one contact opening.

12. The method according to claim 11, wherein the coating in method step b) is carried out using a conductive ink.

13. The method according to claim 11, wherein the coating in method step c) is carried out by means of a lamination step.

14. The method according to claim 11, wherein after method step b), in a method step b1), a contact point according to any of claims 4 to 6 is arranged on the conductor layer.

15. The method according to claim 11, wherein method step e) is carried out by means of laser ablation.
